(19) United States
(12) Patent Application Publication
(10) Pub. No.: US 2017/0104034 A1
(43) Pub. Date: Apr. 13, 2017

(54) DISPLAY DEVICE

(71) Applicant: Japan Display Inc., Minato-ku (JP)

(72) Inventors: Tetsuya NAGATA, Minato-ku (JP); Naoya KUBOTA, Minato-ku (JP)

(73) Assignee: Japan Display Inc., Minato-ku (JP)

(21) Appl. No.: 15/275,788

(22) Filed: Sep. 26, 2016

(30) Foreign Application Priority Data
Oct. 9, 2015 (JP) 2015-201552

(51) Int. Cl. H01L 27/32; H01L 51/52; G02B 5/20

(52) U.S. Cl. CPC H01L 27/322; G02B 5/201; H01L 27/3211; H01L 51/5246; H01L 51/5284

(57) ABSTRACT

A display device includes a first substrate provided with at least one color filter layer that transmits light of a certain wavelength, a second substrate that is disposed opposed to the first substrate; and a fill layer disposed between the first substrate and the second substrate. The first substrate is provided with a display region in which the at least one color filter layer is disposed and which displays an image and a peripheral region that is positioned out of the display region. Wettability of a surface of the at least one color filter layer of the peripheral region is equal to or less than wettability of a surface of the at least one color filter layer of the display region.

### CROSS-REFERENCE TO RELATED APPLICATION

The present application claims priority from the Japanese Application JP2015-201552. The Japanese Application JP2015-201552 is incorporated by reference into this application.

### BACK GROUND OF THE INVENTION

1. Field of the Invention

The present invention relates to a display device.

2. Description of the Related Art

In recent years, a thin display device such as an organic EL display device and a liquid crystal display device has been astonishingly improved, due to its characteristics such as a thinness, a lightness, and a low power consumption, as what can be replaced with a CRT that has been a mainstream of a conventional display device. A thin display device includes an array substrate that is a base material and an opposing substrate that is disposed opposed to the array substrate. The thin display device is generally manufactured by laminating the array substrate, on which a light emitting element and a color filter are formed, and the opposing substrate to each other. Therefore, in order to improve a display quality, for the thin display device, a technology of laminating and a technology of manufacturing a color filter used for color displaying are important.

For example, Japanese Patent No. 3034669 describes forming a black matrix between pixels inside an effective display region on a substrate and a frame-like black mask outside the effective display region. In addition, it describes forming a color pixel inside the effective display region and then forming a dummy film made of the same material as the color pixel outside the effective region, and thereafter polishing the surface of the color filter. Further, it is disclosed that a flatness of the color filter is improved according to this configuration and thus a uniform display over a large area is achieved.

### SUMMARY OF THE INVENTION

A display device of a conventional technology is formed by laminating an array substrate and an opposing substrate together using an adhesive such as a fill agent. However, as Japanese Patent No. 3034669 describes, for example, in the conventional technology, a difference in wettability between the display region and a peripheral region is not considered. Therefore, when the fill agent is dropped on the array substrate, there possibly occurs a phenomenon that the fill agent dropped on both the display region and the peripheral region where the black matrix is disposed spreads towards the black matrix side due to the difference in the wettability between the display region and the peripheral region.

Specifically, as in FIG. 11A for example, in a case where a fill agent 204 is dropped on both a display region 207 and a peripheral region 208, the spreading manners of the fill agent 204 dropped inside the display region 207 and the fill agent 204 dropped on the peripheral region 208 may not be uniform as in FIG. 11B due to a difference in the wettability between the display region 207 and the peripheral region 208. In this case, when the array substrate and the opposing substrate are laminated, bubbles are generated near the peripheral region 208, which causes a display defect. The present invention has been made in view of the above problem, and an object thereof is to provide a display device that prevents a generation of bubbles near the display region that causes a display defect.

According to one aspect of the present invention, a display device includes a first substrate provided with at least one color filter layer that transmits light of a certain wavelength, a second substrate that is disposed opposed to the first substrate; and a fill layer disposed between the first substrate and the second substrate. The first substrate is provided with a display region in which the at least one color filter layer is disposed and which displays an image and a peripheral region that is positioned out of the display region. Wettability of a surface of the at least one color filter layer of the peripheral region is equal to or less than wettability of a surface of the at least one color filter layer of the display region.

In one embodiment of the present invention, the display region includes a plurality of pixel structures. The at least one color filter layer comprising a plurality of color filter layers that transmit light in colors different from one another is disposed in each of the pixel structures and each of the pixel structures is composed of a pixel in which a plurality of subpixels formed in a matrix arrangement compose a unit. The at least one color filter layer of the peripheral region is formed using a material that is the same as a material of the at least one color filter layer of the display region.

In one embodiment of the present invention, the at least one color filter layer of the peripheral region is formed in an arrangement that is the same as an arrangement of the at least one color filter layer of the display region.

In one embodiment of the present invention, an uneven shape of the surface of the at least one color filter layer of the peripheral region is formed so as to be the same as an uneven shape of the surface of the at least one color filter layer of the display region.

In one embodiment of the present invention, the at least one color filter layer of the peripheral region is seamlessly disposed in the peripheral region.

In one embodiment of the present invention, a light shading film that shades light is further disposed in the peripheral region and the at least one color filter layer of the peripheral region is formed on the upper side of the light shading film.

In one embodiment of the present invention, the at least one color filter layer of the peripheral region is formed to be thicker than the at least one color filter layer of the display region.

### BRIEF DESCRIPTION OF THE DRAWINGS

FIG. 1 is a schematic illustration of a display device according to an embodiment of the present invention.

FIG. 2 is an illustration of a configuration of an organic EL panel seen from a display side.

FIG. 3 is an illustration of a magnified view of a region near a frame of an organic EL panel according to the first embodiment.

FIGS. 4A-4C are illustrations of IV-IV′ cross section in FIG. 3.

FIG. 5 is an illustration of a magnified view of a region near a frame of an organic EL panel according to the second embodiment.

FIGS. 6A-6C are illustrations of VI-VI′ cross section in FIG. 5.

FIG. 7 is an illustration of a magnified view of a region near a frame of an organic EL panel according to the third embodiment.

FIGS. 8A-8B are illustrations of VIII-VIII′ cross section in FIG. 7.

FIG. 9 is an illustration of a magnified view of a region near a frame of an organic EL panel according to a variation.

FIGS. 10A-10B are illustrations of X-X′ cross section in FIG. 9.

FIGS. 11A-11B are illustrations of how a fill agent spreads in a conventional technology.

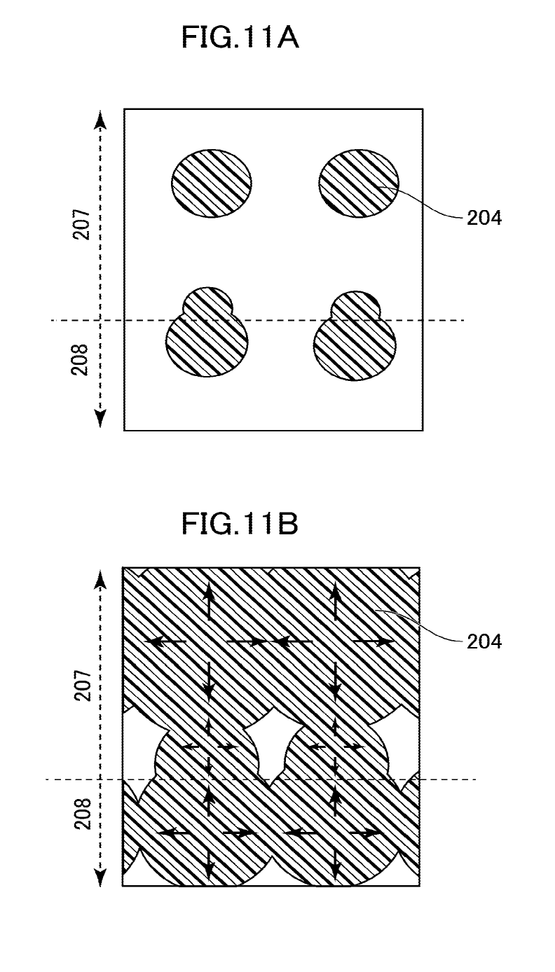

### DETAILED DESCRIPTION OF THE INVENTION

Below, each of the embodiments of the present invention is explained with reference to the accompanying drawings. It is to be noted that the disclosure herein is merely an example, and any modification coming within the spirit of the present invention and obvious to those skilled in the art is intended to be included within the scope of the invention as a matter of course. The accompanying drawings schematically illustrate widths, thicknesses, shapes, or other characteristics of each part for clarity of illustration, compared to actual configurations. However, such a schematic illustration is merely an example and not intended to limit the present invention. In the present specification and drawings, some elements identical or similar to those shown previously are denoted by the same reference signs as the previously shown elements, and thus repetitive detailed descriptions of them may be omitted as appropriate.

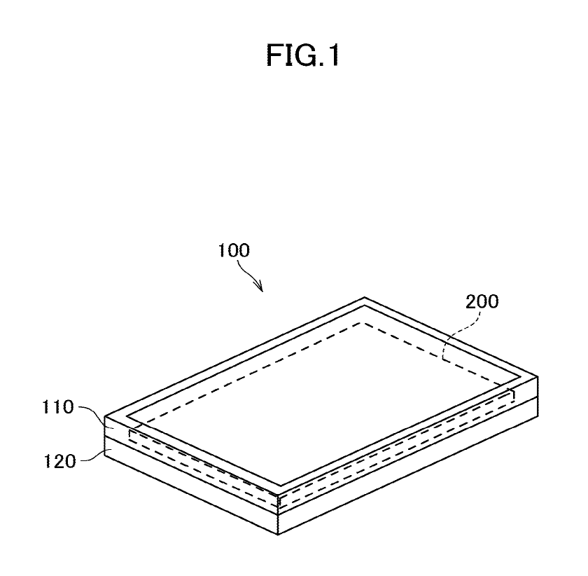

FIG. 1 schematically illustrates a display device 100 according to an embodiment of the present invention. As illustrated in FIG. 1, the display device 100 is composed of an organic EL panel 200 that is fixed so as to be sandwiched by an upper frame 110 and a lower frame 120. In this embodiment, although a case of the organic EL display device is given as a disclosure example, any kinds of flat panel display devices, such as a liquid crystal display device, other light-emitting display devices, and electronic paper display device having electrophoretic elements, can be mentioned as other application examples. Further, needless to say, it is applicable to devices from a small/medium type to a large type with no specific limitation.

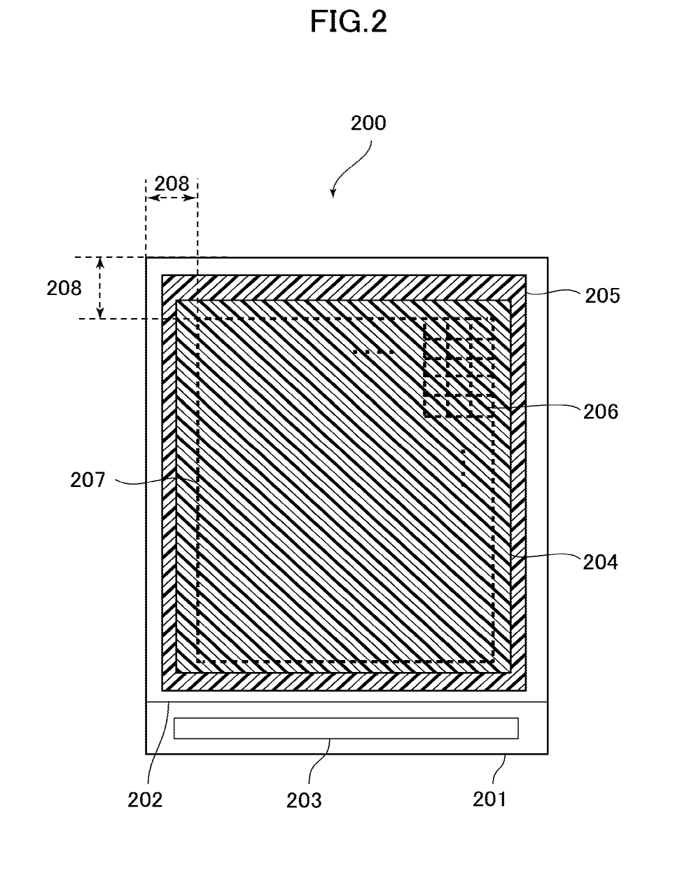

FIG. 2 schematically illustrates the configuration of the organic EL panel 200 of FIG. 1. As illustrated in FIG. 2, the organic EL display panel 200 has a lower glass substrate 201, an upper glass substrate 202, and a driving IC (Integrated Circuit) 203. An organic EL layer and a color filter layer to be described later, for example, are disposed on the lower glass substrate 201, which is bonded to the upper glass substrate 202 with a fill agent 204 and a dam agent 205. The driving IC 203 applies an electric potential to a scan signal line of a pixel transistor disposed in each subpixel 206 to be described later for electrically connecting a source and a drain, and at the same time applies an electric voltage that corresponds to a gradation value of the subpixel 206 to a data signal line of each pixel transistor, for example.

Further, the lower glass substrate 201 is provided with the color filter layer that transmits light of a certain wavelength. Moreover, the lower glass substrate 201 is provided with a display region 207 that includes the color filter layer and displays an image, and a peripheral region 208 which is positioned outside the display region 207. Specifically, for example, the lower glass substrate 201 is provided with the display region 207 that has a plurality of pixel structures on which the color filter layer to transmit light of a certain wavelength is disposed, and the peripheral region 208 having light shading properties, which is arranged outside the display region 207 and is formed by disposing an adjustment film for adjusting the wettability on a surface of the lower glass substrate 201. Here, the color filter layer is composed of a color filter that transmits light of a predetermined color, such as red, green, and blue. The adjustment film, a detail of which will be described later, is a layer formed for controlling the wettability of the peripheral region, and is formed using, for example, a material that is the same as those of the color filter layer and the light shading film 306. The pixel structure is arranged such that color filter layers transmitting light of colors different from one another are disposed, and is composed of a pixel in which a plurality of subpixels 206 formed in a matrix arrangement composes a unit.

### First Embodiment

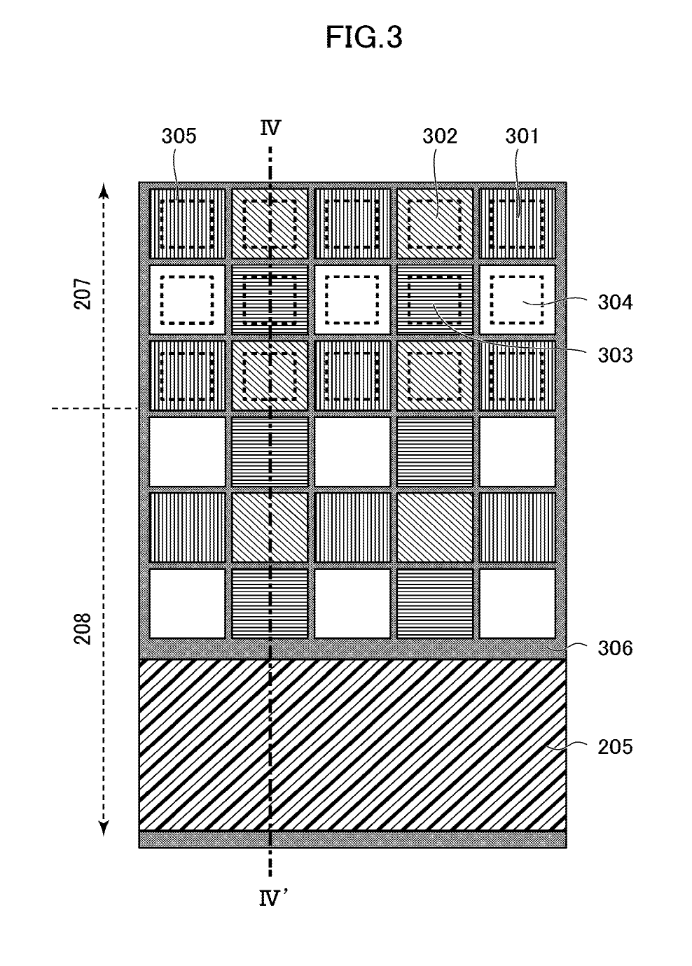

Subsequently, a structure near a frame of the organic EL panel 200 is explained. FIG. 3 illustrates a magnified view of a region near the frame of the organic EL panel 200 in FIG. 2. As illustrated in FIG. 3, in the display region 207, the subpixels 206 on which one of a red color filter 301, a green color filter 302, a blue color filter 303, and a white color filter 304 is disposed are provided. One pixel is made up by combining the subpixels 206 where the colors filters of the four colors are disposed in a two by two matrix arrangement. Specifically, among four subpixels 206 constituting one pixel, the upper-left subpixel 206 is provided with the green color filter 302, the upper-right subpixel 206 is provided with the red color filter 301, the lower-left subpixel 206 is provided with the blue color filter 303, and the lower-right subpixel 206 is provided with the white color filter 304. Further, each subpixel 206 arranged in the display region is provided with an organic EL light emitting layer on the lower layer side of the color filter, and has an organic EL light emitting part 305 as illustrated in FIG. 3. Further, between each subpixel 206 of the display region 207, the light shading film 306 for shading light emitted by neighboring subpixels 206 is disposed.

In the peripheral region 208, the adjustment film formed using a material of the color filter layer disposed in the respective subpixels 206 is formed. Here, the adjustment film is formed in the same arrangement as the color filter layers disposed in the respective subpixels 206. Specifically, in the peripheral region 208, the adjustment films of the same materials as those of the color filters of red, green, blue, and white are disposed in the arrangement pattern of a two by two matrix that is the same as that in the display region 207. Although in FIG. 3, the adjustment films corresponding to one and a half pixels are provided in the peripheral region 208, the adjustment films corresponding to one pixel, or those corresponding to two or more pixels may be provided as well. Moreover, the light shading film 306 is disposed between the adjustment films disposed in the peripheral region 208, similarly to the display region 207. Further, the dam agent 205 is formed outside the adjustment film.

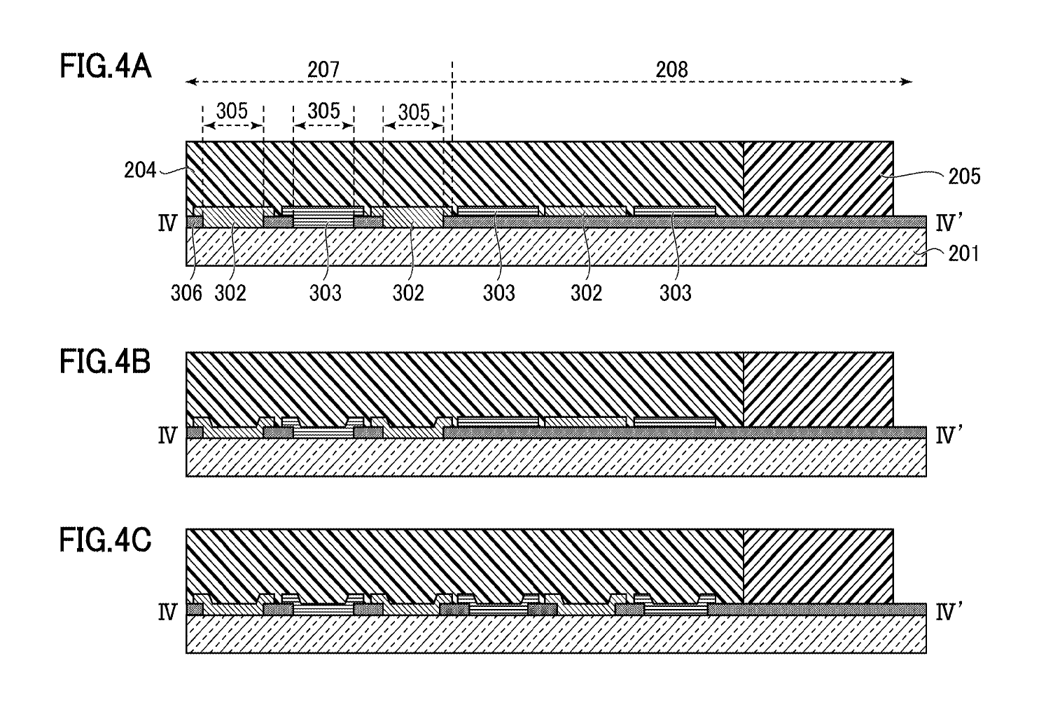

Next, a cross sectional structure of a region near the frame of the organic EL panel 200 is explained. FIGS. 4A to 4C illustrate IV-IV′ cross section in FIG. 3. As illustrated in FIGS. 4A to 4C, the green color filter 302 and the blue color filter 303 are alternatively disposed in the display region 207, and the light shading film 306 is disposed between respective color filters. Further, in the peripheral region 208, the light shading film 306 is disposed on the surface of the lower glass substrate 201 so as to cover the peripheral region 208. On the upper side of the light shading film 306, the dam agent 205 is disposed near the frame, and the green color filter 302 and the blue color filter 303 are disposed alternatively inside the dam agent 205.

Here, it is desirable that an uneven shape of the surface of the adjustment films is formed to be the same as an uneven shape of the surface of the color filter layers formed in the display region 207. Specifically, as shown in FIG. 4A, for example, it is desirable that the surface shape of the color filter layers in the display region 207 and the surface shape of the adjustment films in the peripheral region 208 are both flat. The wettability of the display region 207 and that of the peripheral region 208 can be made substantially the same by not only using the same materials for the color filter layers of the display region 207 as those of the adjustment films of the peripheral region 208, but also by making the surface shape of the color filter layers of the display region 207 the same as that of the adjustment films of the peripheral region 208. However, in the organic EL light emitting part 305 in the display region 207, an opening is formed in the light shading film 306 to let the light go out of the display device 100. Thus, as shown in FIG. 4B, the color filter layer may be configured to have a recessed part in the organic light emitting part 305, but the color filter layer may be of such a configuration. Even in the case of such a configuration, the wettability of the display region 207 and that of the peripheral region 208 can be made substantially the same by using the same materials for the color filter layers of the display region 207 as those of the color filter layers of the peripheral region 208.

Further, as in FIG. 4C, in the case of the configuration where the color filter layers have the recessed part in the organic EL light emitting part 305, it may be configured that the adjustment films disposed in the peripheral region 208 are provided with the same recess part as that of the color filter layers of the display region 207 by providing opening parts in the light shading film 306 disposed in the peripheral region 208. According to this configuration, similarly to the configuration illustrated in FIG. 4A, the wettability of the display region 207 and that of the peripheral region 208 can be made substantially the same by making the materials and the surface shape of adjustment films of the peripheral region 208 the same with those of the color filter layers of the display region 207.

Regarding this embodiment, although the case has been described where both of the color filter layers and the adjustment films are color filters of red, green, blue, and white, the color filter layers and the adjustment films are not limited to the above case, and can be as described in embodiments below.

### Second Embodiment

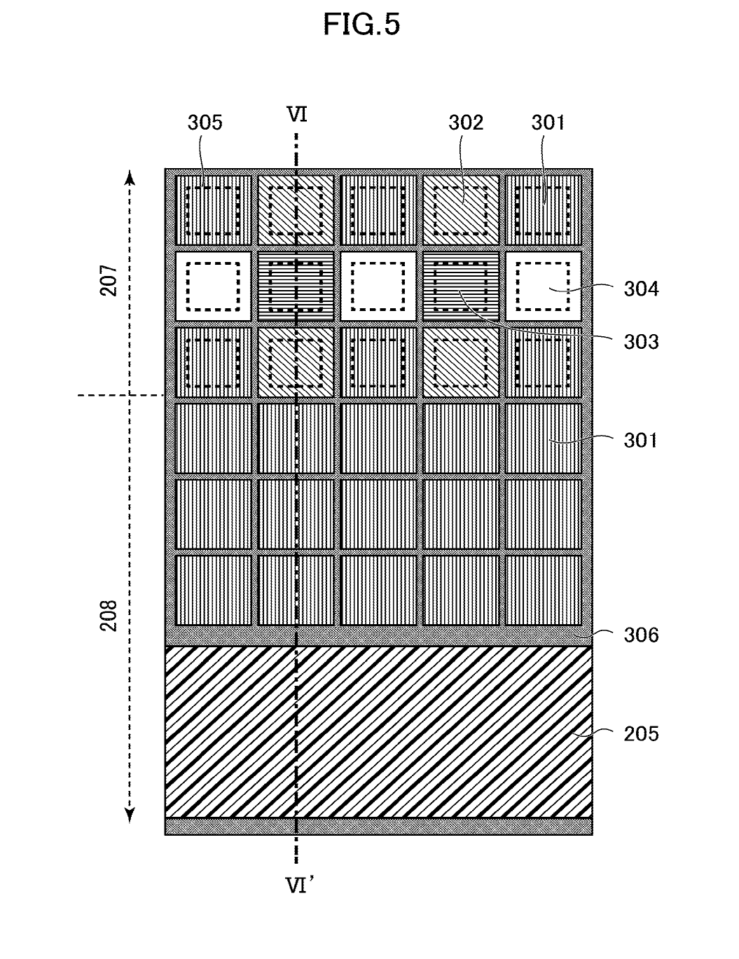

FIG. 5 illustrates a magnified view of a region near the frame of the organic EL panel 200 according to the second embodiment. In this embodiment, the configuration of the display region 207 is the same as that of the first embodiment. In the peripheral region 208, the adjustment films are formed using the material of the color filter layer disposed in one of the subpixels 206 included in a pixel. Specifically, in the peripheral region 208, the adjustment films made of the same material as that of the red color filter 301 is formed in a matrix arrangement. Further, the dam agent 205 is formed outside the adjustment films.

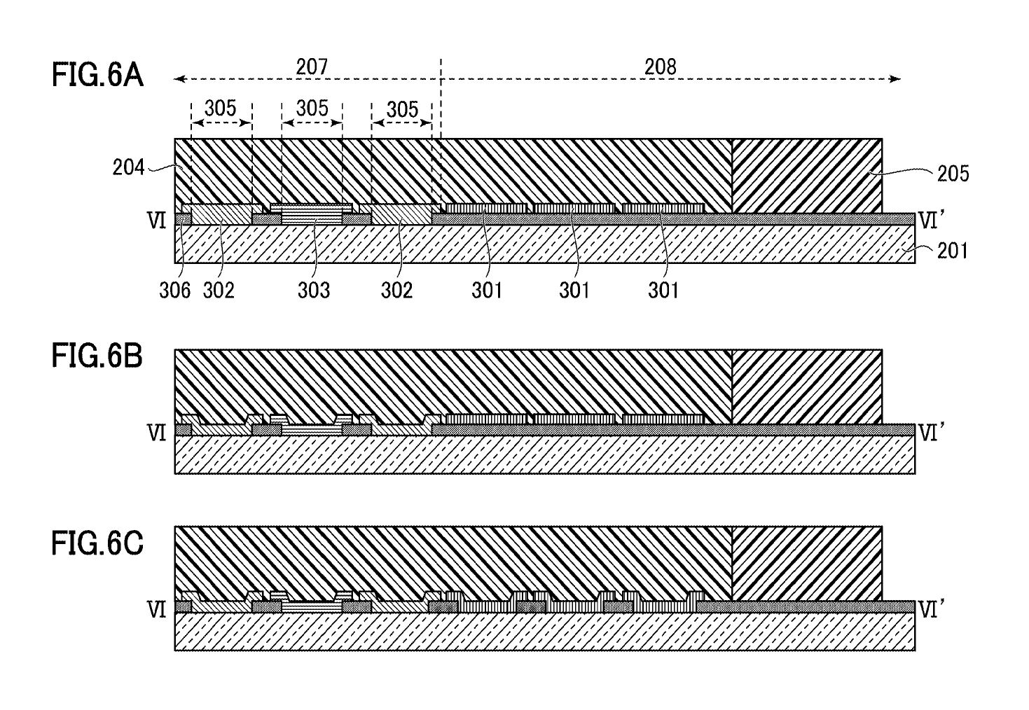

FIGS. 6A to 6C illustrate IV-IV′ cross section in FIG. 5. As illustrated in FIGS. 6A and 6B, the green color filter 302 and the blue color filter 303 are alternatively disposed in the display region 207, and the light shading film 306 is disposed between respective color filters. Further, in the peripheral region 208, the light shading film 306 is disposed on the surface of the lower glass substrate 201 so as to cover the peripheral region 208. On the upper side of the light shading film 306, the dam agent 205 is disposed near the frame, and the red color filters 301 are disposed side by side inside the dam agent 205.

Similarly to the first embodiment, as shown in FIG. 6A, the surface shape of the color filter layers of the display region 207 may be configured to be flat, and as shown in FIG. 6B, the color filter layers may be configured to have the recessed part in the organic EL light emitting part 305. Further, similarly to the first embodiment, the adjustment films may be formed of the same material as that of the color filters in other colors disposed in the display region 207. Moreover, as shown in FIG. 6C, in the case of the configuration where the color filter layers have the recessed part in the organic EL light emitting part 305, the adjustment films disposed in the peripheral region 208 may be provided with the same recess part as that of the color filter layers of the display region 207.

As described above, in this embodiment, the adjustment films disposed in the peripheral region 208 may be composed of the color filter of one color from among the color filters of the plurality of colors provided in the subpixels 206 in the display region 207. By disposing, in the peripheral region 208, the adjustment films made of the same material as that of some of the color filter layers disposed in the display region 207, the wettability of the display region 207 can be made substantially the same as that of the peripheral region 208.

### Third Embodiment

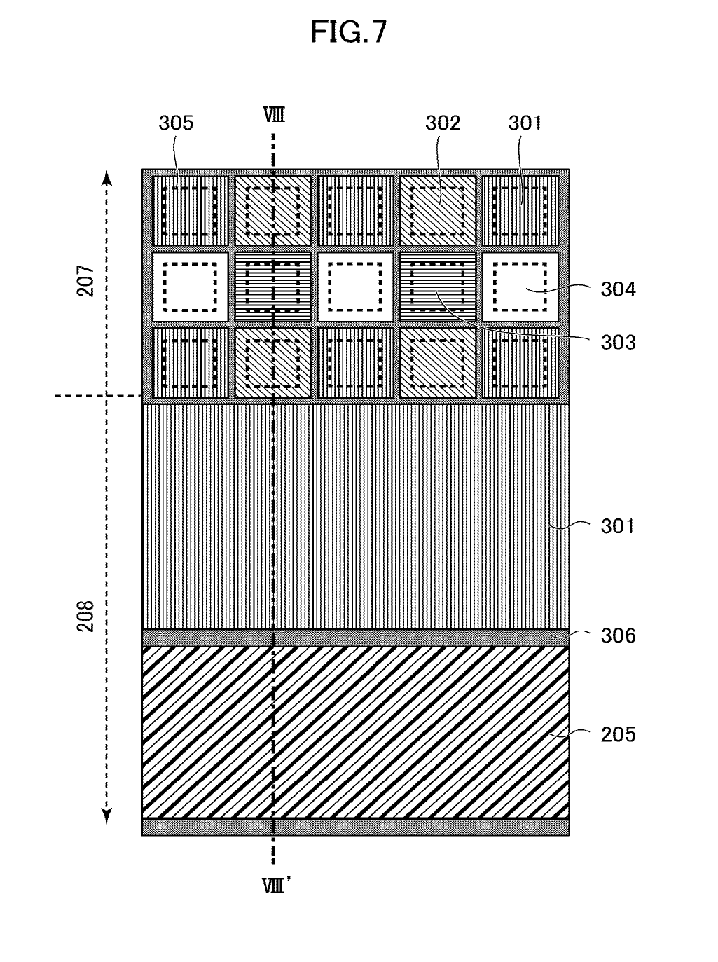

FIG. 7 illustrates a magnified view of a region near the frame of the organic EL panel 200 according to the third embodiment. In this embodiment, the configuration of the display region 207 is the same as that of the first embodiment. In the peripheral region 208, the adjustment film formed of the same material as that of the color filter layer disposed in one of the subpixels 206 included in a pixel is seamlessly disposed. Specifically, in the peripheral region 208, the adjustment film made of the same material as that of the red color filter 301 is seamlessly disposed between the display region 207 and the dam agent 205.

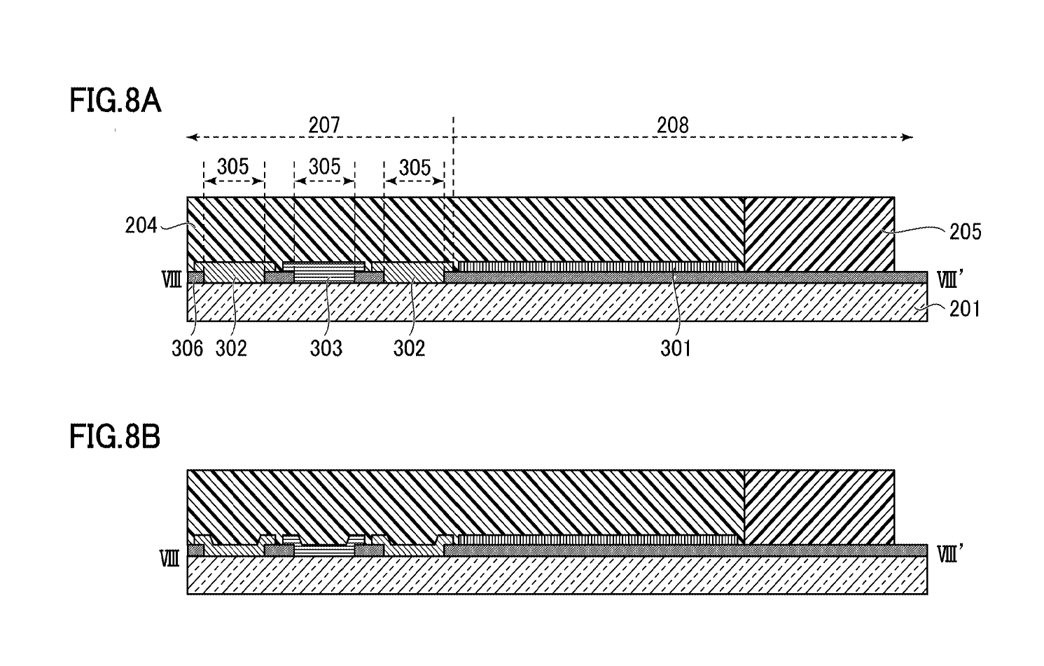

FIGS. 8A and 8B illustrate VIII-VIII′ cross section in FIG. 7. The configuration of the display region 207 is the same as those of the first and the second embodiments. In the peripheral region 208, the light shading film 306 is disposed on the surface of the lower glass substrate 201 so as to cover the peripheral region 208. On the upper side of the light shading film 306, the dam agent 205 is disposed near the frame, and the red color filter 301 is seamlessly disposed inside the dame agent 205. Similarly to the first and the second embodiments, the color filter layers of the display region 207 may be configured to be flat as shown in FIG. 8A, and the color filter layers may be configured to have the recessed part in the organic light emitting part 305 as shown in FIG. 8A.

As described above, in the first and the second embodiments, the adjustment films of the peripheral region 208 are formed in a matrix arrangement, while this embodiment is different from them in that the adjustment film of the peripheral region 208 is seamlessly formed. Even if the shape of the color filter layers disposed in the display region 207 and the shape of the adjustment film provided in the peripheral region 208 are different as in this embodiment, it is possible to make the wettability of the display region 207 substantially the same as that of the peripheral region 208, by disposing, in the peripheral region 208, the adjustment film made of the same material as some of the color filter layers disposed in the display region 207.

Although as for the first to the third embodiments above, a case has been explained where the adjustment film is formed as thick as the color filter layer, the adjustment film may be formed to be thicker than the color filter layer. Specifically, for example, in the first to the third embodiments, the color filter in a color such as red disposed in the peripheral region 208 may be formed to be thicker than the color filter disposed in the display region 207. According to such a configuration, the fill agent 204 dropped on a region near the border of the display region 207 and the peripheral region 208 flows toward the display region 207 due to the gravity, and this gives the same effect as making the wettability of the peripheral region 208 lower than that of the display region 207.

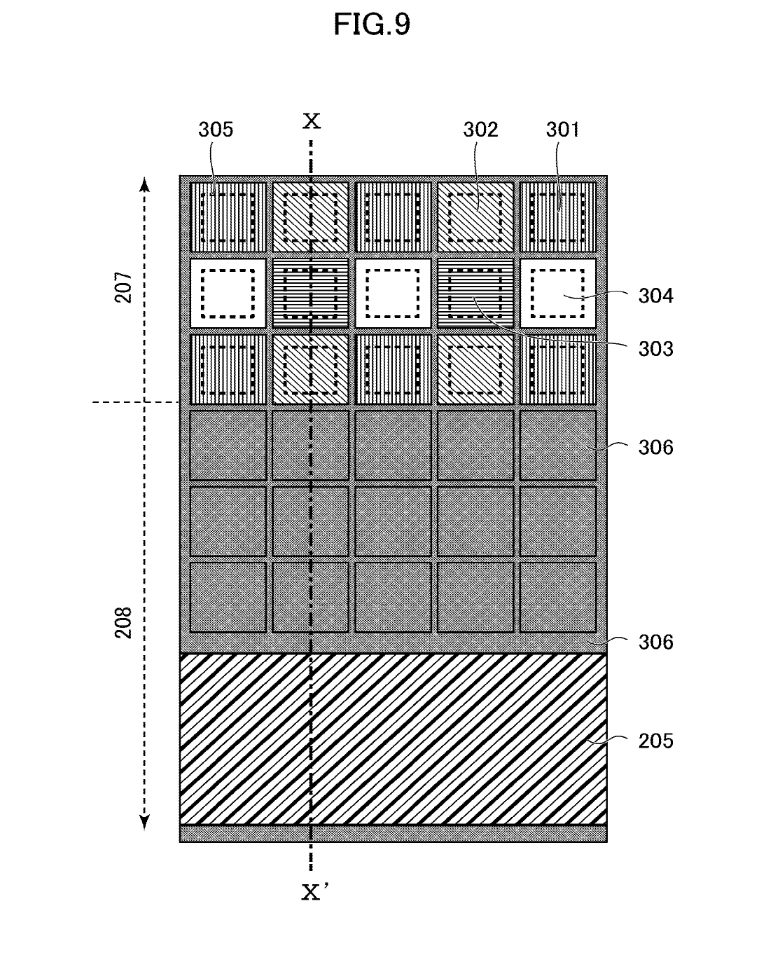

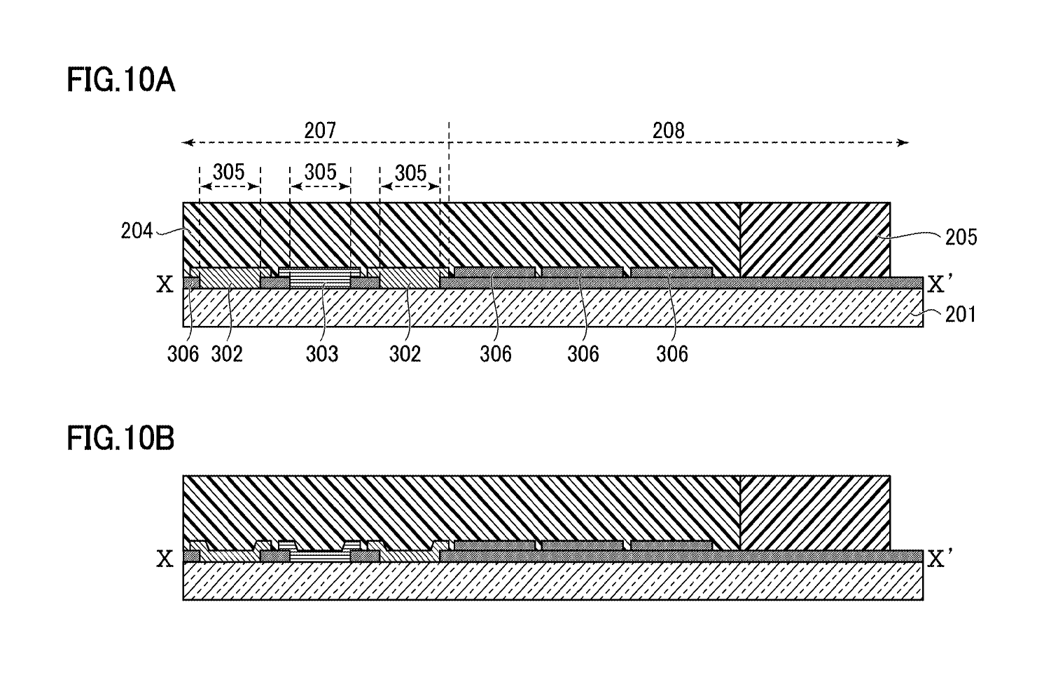

Further, according to a variation as follows, the wettability of the peripheral region 208 can be made equal to or lower than that of the display region 207. FIG. 9 illustrates a magnified view of a region near the frame of the organic EL panel 200 according to this variation, and FIGS. 10A and 10B illustrate X-X′ cross section in FIG. 9. In this variation, the configuration of the display region 207 is also the same as those of the first to the third embodiments. Meanwhile, in the peripheral region 208, the light shading film 306 is disposed on the surface of the lower glass substrate 201 so as to cover the peripheral region 208. On the upper side of the light shading film 306, the dam agent 205 is disposed near the frame, and inside the dam agent 205 the adjustment films formed of the same material as that of the light shading film 306 are further disposed.

Here, the adjustment films disposed on the upper layer side of the light shading film 306 arranged so as to cover the peripheral region 208 may be formed in a matrix arrangement as shown in FIGS. 10A and 10B, and may be seamlessly formed as described in the third embodiment. Further, similarly to the first embodiment, the surface shape of the color filter layers of the display region 207 may be configured to be flat as shown in FIG. 10A, and the color filter layers may be configured to have the recessed part in the organic EL light emitting part 305 as shown in FIG. 10B.

In the case where the color filter layer is formed with the color filter and the adjustment film is formed with the light shading film 306 as the above variation, although the material of the color filter layer and that of the adjustment film are different, the wettability of the display region 207 and that of the peripheral region 208 can be made substantially the same by making the surface shape of the color filter layer the same as that of the adjustment film.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a first substrate provided with at least one color filter layer that transmits light of a certain wavelength;
a second substrate that is disposed opposed to the first substrate; and
a fill layer disposed between the first substrate and the second substrate, wherein
the first substrate is provided with a display region in which the at least one color filter layer is disposed and which displays an image and a peripheral region that is positioned out of the display region; and
wettability of a surface of the at least one color filter layer of the peripheral region is equal to or less than wettability of a surface of the at least one color filter layer of the display region.

2. The display device according to claim 1, wherein
the display region includes a plurality of pixel structures,
the at least one color filter layer comprising a plurality of color filter layers that transmit light in colors different from one another is disposed in each of the pixel structures and each of the pixel structures is composed of a pixel in which a plurality of subpixels formed in a matrix arrangement compose a unit, and
the at least one color filter layer of the peripheral region is formed using a material that is the same as a material of the at least one color filter layer of the display region.

3. The display device according to claim 2, wherein the at least one color filter layer of the peripheral region is formed in an arrangement that is the same as an arrangement of the at least one color filter layer of the display region.

4. The display device according to claim 3, wherein an uneven shape of the surface of the at least one color filter layer of the peripheral region is formed so as to be the same as an uneven shape of the surface of the at least one color filter layer of the display region.

5. The display device according to claim 2, wherein the at least one color filter layer of the peripheral region is seamlessly disposed in the peripheral region.

6. The display device according to claim 1, wherein a light shading film that shades light is further disposed in the peripheral region and the at least one color filter layer of the peripheral region is formed on the upper side of the light shading film.

7. The display device according to claim 1, wherein the at least one color filter layer of the peripheral region is formed to be thicker than the at least one color filter layer of the display region.
